(19) United States
(12) Patent Application Publication
(10) Pub. No.: US 2025/0115691 A1
(43) Pub. Date: Apr. 10, 2025

(54) METHOD OF FORMING PATTERNS

(71) Applicant: SAMSUNG SDI CO., LTD., Yongin-si (KR)

(72) Inventors: Seung-Wook Shin, Suwon-si (KR); Seunghyun Kim, Suwon-si (KR); Yushin Park, Suwon-si (KR)

(21) Appl. No.: 18/982,447

(22) Filed: Dec. 16, 2024

Related U.S. Application Data
(63) Continuation of application No. 18/242,643, filed on Sep. 6, 2023.
Application No. 18/242,643 is a division of application No. 16/543,875, filed on Aug. 19, 2019, now abandoned.

(30) Foreign Application Priority Data
Aug. 21, 2018 (KR) 10-2018-0097581

(51) Int. Cl. C08F 138/00; C09D 149/00; G03F 7/00; G03F 7/016; G03F 7/16; G03F 7/20; G03F 7/26; H01L 21/02; H01L 21/027; H01L 21/3105

(52) U.S. Cl. CPC C08F 138/00; C09D 149/00; G03F 7/016; H01L 21/02118; H01L 21/02282; H01L 21/0274; H01L 21/31058; G03F 7/0017; G03F 7/16; G03F 7/20; G03F 7/26; H01L 21/0271

(57) ABSTRACT

A polymer, an organic layer composition, and a method of forming patterns, the polymer including a structural unit represented by Chemical Formula 1 or Chemical Formula 2:

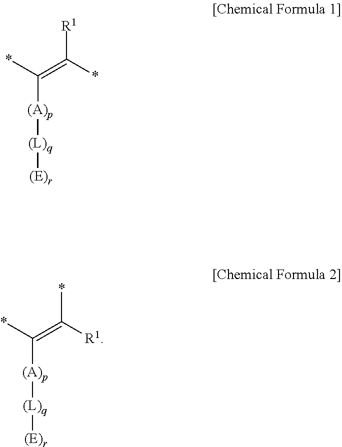

### CROSS-REFERENCE TO RELATED APPLICATIONS

This is a continuation application based on pending application Ser. No. 18/242,643, filed Sep. 6, 2023, which in turn is a divisional application based on application Ser. No. 16/543,875, filed Aug. 19, 2019, now abandoned, the entire contents of both being hereby incorporated by reference.

Korean Priority Patent Application No. 10-2018-0097581, filed on Aug. 21, 2018, in the Korean Intellectual Property Office, and entitled: “Polymer, Organic Layer Composition and Method of Forming Patterns,” is incorporated by reference herein in its entirety.

### BACKGROUND

### 1. Field

Embodiments relate to a polymer, an organic layer composition including the polymer, and a method of forming patterns using the organic layer composition.

### 2. Description of the Related Art

The semiconductor industry has developed to an ultra-fine technique having a pattern of several to several tens of nanometer size. Such ultrafine technique use effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a polymer comprising a structural unit represented by Chemical Formula 1 or Chemical Formula 2:

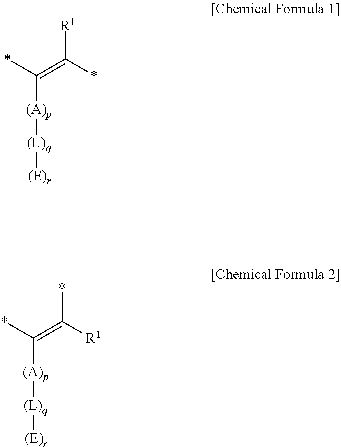

wherein, in Chemical Formula 1 and Chemical Formula 2, E is a substituted or unsubstituted C6 to C30 aryl group, a substituted or unsubstituted C2 to C30 heterocyclic group, or a combination thereof, A is a single bond, a substituted or unsubstituted C1 to C20 alkylene group, a substituted or unsubstituted C6 to C30 arylene group, a substituted or unsubstituted C2 to C30 heteroarylene group, or a combination thereof, L is a single bond, O, S, NR^{a}, a carbonyl group, a substituted or unsubstituted C1 to C20 alkylene group, a substituted or unsubstituted C2 to C20 alkenylene group, a substituted or unsubstituted C2 to C20 alkynylene group, a substituted or unsubstituted C6 to C30 arylene group, or a combination thereof, R^{a} and R^{l} are each independently a hydrogen, a hydroxy group, a halogen, a substituted or unsubstituted C1 to C30 alkyl group, a substituted or unsubstituted C6 to C30 aryl group, a substituted or unsubstituted C2 to C30 heterocyclic group, or a combination thereof, p and q are each independently an integer of 0 to 4, r is an integer of 1 to 5, and * is a linking point.

E may be a group of the following Group I:

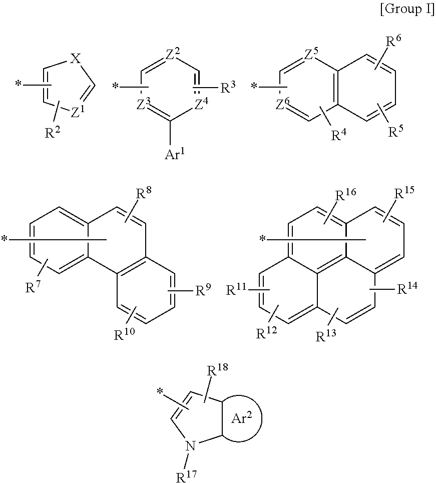

wherein, in the groups of Group I, Ar¹ may be a substituted or unsubstituted C6 to C30 non-fused aryl group, Ar² may be a substituted or unsubstituted 4-membered ring, a substituted or unsubstituted 5-membered ring, a substituted or unsubstituted 6-membered ring, or a fused ring thereof, X may be N, NR^{b}, O, or S, Z¹ to Z⁶ may be each independently N, C, or CR^{c}, R^{b}, R¹ and R² to R¹⁸ may be each independently hydrogen, a hydroxy group, a halogen, a nitro group, a carboxyl group, a substituted or unsubstituted imine group, a substituted or unsubstituted C1 to C30 alkyl group, a substituted or unsubstituted C1 to C30 alkoxy group, a substituted or unsubstituted C6 to C30 aryl group, a substituted or unsubstituted C2 to C30 heteroaryl group, or a combination thereof, and * is a linking point.

E may be a group of the following Group I-1:

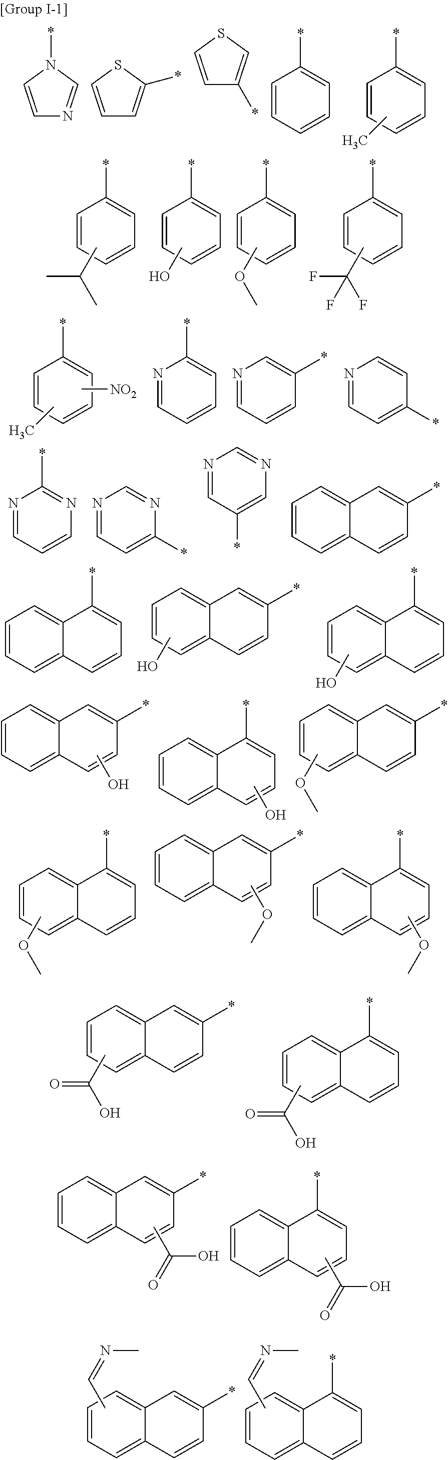

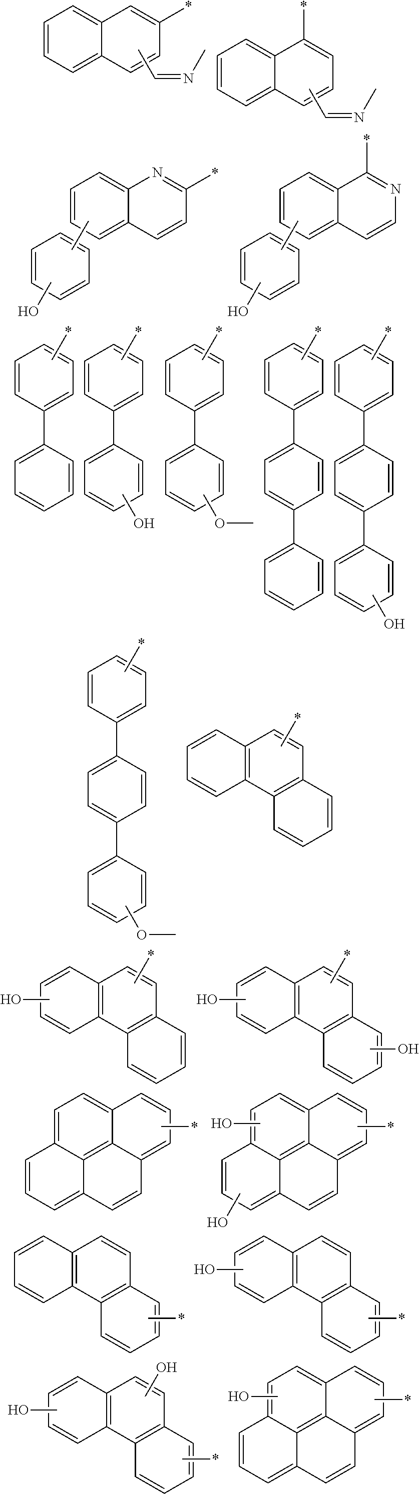

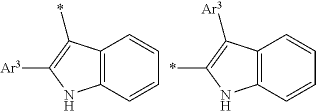

wherein, in Group I-1, Ar³ may be a C1 to C10 alkyl group or a C6 to C18 aryl group, and * is a linking point.

At least one of R¹ and E may include a hydroxy group thereon.

E may be a substituted or unsubstituted C6 to C30 non-fused aryl group, a substituted or unsubstituted naphthyl group, a substituted or unsubstituted quinolinyl group, or a substituted or unsubstituted indolyl group.

E may be a substituted or unsubstituted biphenyl group, a substituted or unsubstituted terphenyl group, a substituted or unsubstituted quaterphenyl group, or a substituted or unsubstituted pentaphenyl group.

The structural unit may be a structural unit of the following Group II:

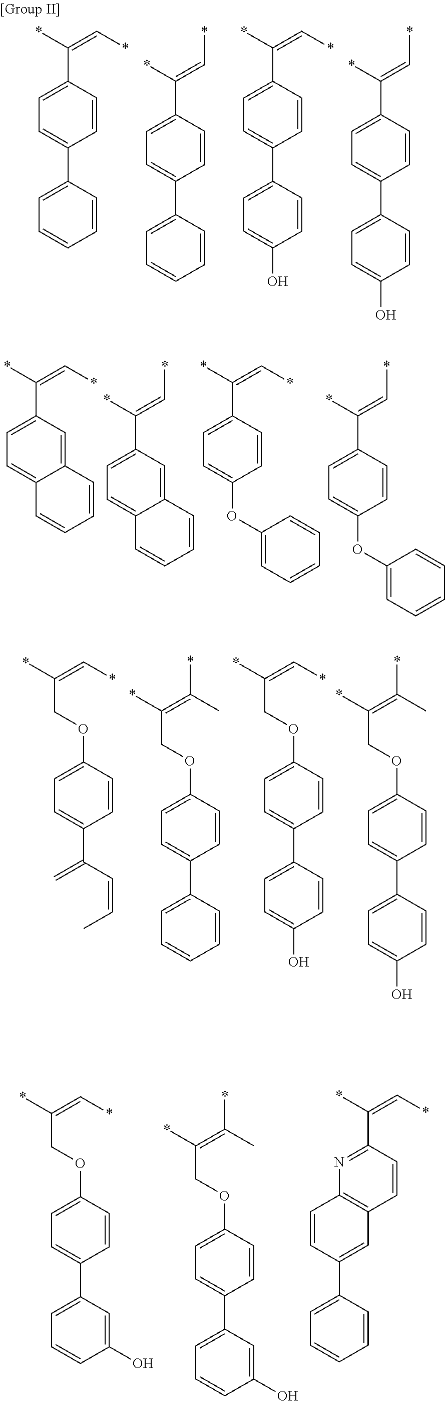

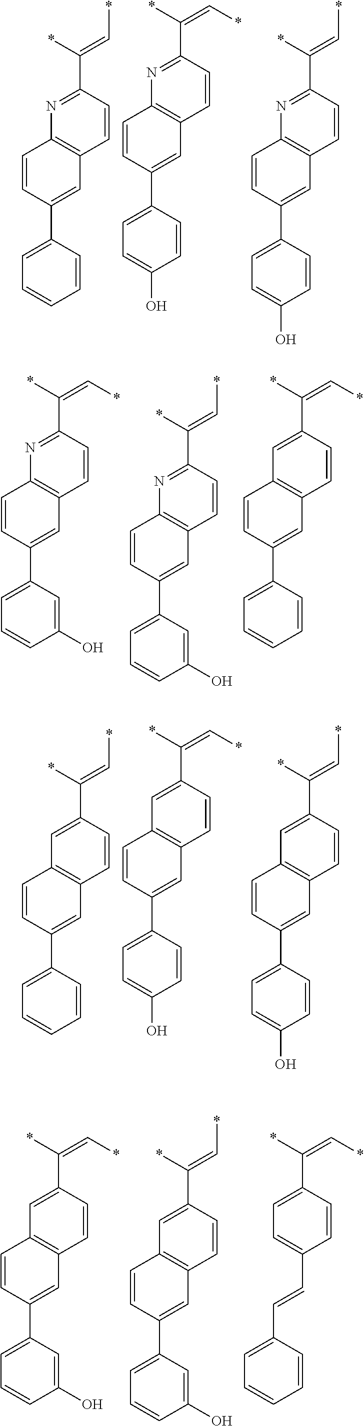

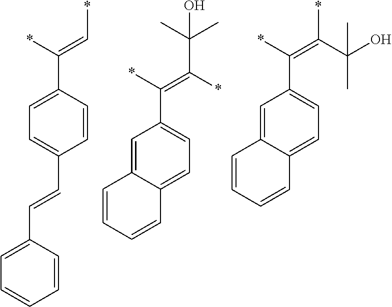

wherein, in Group II, * is a linking point.

The polymer may have a weight average molecular weight of about 1,000 to about 200,000.

The embodiments may be realized by providing an organic layer composition including the polymer according to an embodiment, and a solvent.

The embodiments may be realized by providing a method of forming patterns, the method including providing a material layer on a substrate, applying the organic layer composition according to an embodiment on the material layer, heat-treating the organic layer composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed portion of the material layer.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not an exclusive term, e.g., A or B would include, A, B, or A and B.

As used herein, when a definition is not otherwise provided, ‘substituted’ may refer to replacement of a hydrogen atom of a compound by a substituent selected from a halogen atom (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heteroaryl group, and a combination thereof.

As used herein, when a definition is not otherwise provided, the term ‘hetero’ refers to one including 1 to 3 heteroatoms selected from N, O, S, and P.

As used herein, “aryl group” may refer to a group including at least one hydrocarbon aromatic moiety, and includes hydrocarbon aromatic moieties linked by a single bond and hydrocarbon aromatic moieties fused directly or indirectly to provide a non-aromatic fused ring. The aryl group may include a monocyclic, polycyclic, or fused polycyclic (i.e., rings sharing adjacent pairs of carbon atoms) functional group.

As used herein, “heterocyclic group” is a concept including a heteroaryl group, and may include at least one hetero atom selected from N, O, S, P, and Si instead of carbon (C) in a cyclic compound such as an aryl group, a cycloalkyl group, a fused ring thereof, or a combination thereof. When the heterocyclic group is a fused ring, the entire ring or each ring of the heterocyclic group may include one or more heteroatoms.

The substituted or unsubstituted aryl group and/or the substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiophenyl group, a substituted or unsubstituted carbazolyl group, pyridoindolyl group, benzopyridooxazinyl group, benzopyridothiazinyl group, 9,9-dimethyl-9,10-dihydroacridinyl group, a combination thereof, or a combined fused ring of the foregoing groups. In one example, the heterocyclic group or the heteroaryl group may be an imidazolyl group, a thiophenyl group, a pyridyl group, a pyrimidinyl group, or an indolyl group.

As used herein, the substituted or unsubstituted arylene group or the substituted or unsubstituted heteroarylene group may be the foregoing substituted or unsubstituted aryl group or substituted or unsubstituted heterocyclic group having two linking groups, for example, a substituted or unsubstituted phenylene group, a substituted or unsubstituted naphthalene group, a substituted or unsubstituted anthracenylene group, a substituted or unsubstituted phenanthrylene group, a substituted or unsubstituted naphthacenylene group, a substituted or unsubstituted pyrenylene group, a substituted or unsubstituted biphenylene group, a substituted or unsubstituted terphenylene group, a substituted or unsubstituted quaterphenylene group, a substituted or unsubstituted chrysenylene group, a substituted or unsubstituted triphenylenylene group, a substituted or unsubstituted perylenylene group, a substituted or unsubstituted indenylene group, a substituted or unsubstituted furanylene group, a substituted or unsubstituted thiophenylene group, a substituted or unsubstituted pyrrolylene group, a substituted or unsubstituted pyrazolylene group, a substituted or unsubstituted imidazolylene group, a substituted or unsubstituted triazolylene group, a substituted or unsubstituted oxazolylene group, a substituted or unsubstituted thiazolylene group, a substituted or unsubstituted oxadiazolylene group, a substituted or unsubstituted thiadiazolylene group, a substituted or unsubstituted pyridinylene group, a substituted or unsubstituted pyrimidinylene group, a substituted or unsubstituted pyrazinylene group, a substituted or unsubstituted triazinylene group, a substituted or unsubstituted benzofuranylene group, a substituted or unsubstituted benzothiophenylene group, a substituted or unsubstituted benzimidazolylene group, a substituted or unsubstituted indolylene group, a substituted or unsubstituted quinolinylene group, a substituted or unsubstituted isoquinolinylene group, a substituted or unsubstituted quinazolinylene group, a substituted or unsubstituted quinoxalinylene group, a substituted or unsubstituted naphthyridinylene group, a substituted or unsubstituted benzoxazinylene group, a substituted or unsubstituted benzthiazinylene group, a substituted or unsubstituted acridinylene group, a substituted or unsubstituted phenazinylene group, a substituted or unsubstituted phenothiazinylene group, a substituted or unsubstituted phenoxazinylene group, a substituted or unsubstituted fluorenylene group, a substituted or unsubstituted dibenzofuranylene group, a substituted or unsubstituted dibenzothiophenylene group, a substituted or unsubstituted carbazolylene group, a combination thereof, or a combined fused ring of the foregoing groups.

As used herein, “non-fused aryl group” may refer to at least one monocyclic aryl group linked with a σ-bond. For example, each ring of the non-fused aryl group may be monocyclic.

For example, “non-fused aryl group” may refer to phenyl groups linked with a σ-bond, and examples may include a substituted or unsubstituted phenyl group, a substituted or unsubstituted biphenyl group, a substituted or unsubstituted terphenyl group, a substituted or unsubstituted quaterphenyl group, and the like.

Hereinafter, a polymer according to an embodiment is described.

A polymer according to an embodiment may include a structural unit represented by Chemical Formula 1 or Chemical Formula 2. For example, the polymer according to an embodiment may include a cis structural unit or a trans structural unit. For example, the polymer may include a carbon-carbon double bond in a backbone thereof.

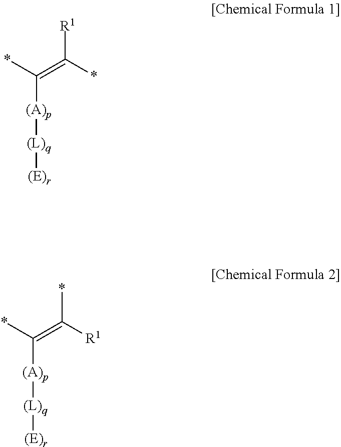

In Chemical Formula 1 and Chemical Formula 2,
E may be or may include, e.g., a substituted or unsubstituted C6 to C30 aryl group, a substituted or unsubstituted C2 to C30 heterocyclic group, or a combination thereof,
A may be or may include, e.g., a single bond, a substituted or unsubstituted C1 to C20 alkylene group, a substituted or unsubstituted C6 to C30 arylene group, a substituted or unsubstituted C2 to C30 heteroarylene group, or a combination thereof,
L may be or may include, e.g., a single bond, O, S, NR^{a}, a carbonyl group, a substituted or unsubstituted C1 to C20 alkylene group, a substituted or unsubstituted C2 to C20 alkenylene group, a substituted or unsubstituted C2 to C20 alkynylene group, a substituted or unsubstituted C6 to C30 arylene group, or a combination thereof,
R^{a} and R^{l} may each independently be or include, e.g., a hydrogen, a hydroxy group, a halogen, a substituted or unsubstituted C1 to C30 alkyl group, a substituted or unsubstituted C6 to C30 aryl group, a substituted or unsubstituted C2 to C30 heterocyclic group, or a combination thereof,
p and q may each independently be, e.g., an integer of 0 to 4,
r may be, e.g., an integer of 1 to 5, and
* is a linking point.

The polymer may include a structural unit of a staggered conformation including a vinyl main chain, may have a high carbon content, may have a solubility in a solvent that is high enough to be effectively applied to a solution process such as a spin coating, and may have an etch resistance that is high enough to tolerate etching gas exposed in the subsequent etching process.

For example, the polymer may help enhance a solubility for an organic solvent due to the structural characteristics of the structural unit included in the polymer even if a hydrophilic functional group such as hydroxy group (—OH) is not included, thereby an affinity to the lower film is increased, so the obtained hardmask layer may have improved film flatness.

In an implementation, E may be a group of the following Group I.

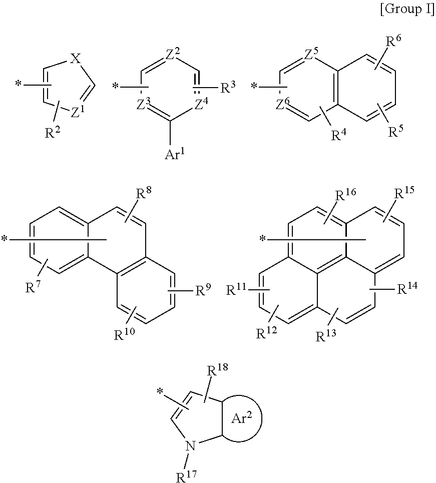

In Group I,
Ar¹ may be, e.g., a substituted or unsubstituted C6 to C30 non-fused aryl group,
Ar² may be, e.g., a substituted or unsubstituted 4-membered (tetragonal) ring, a substituted or unsubstituted 5-membered (pentagonal) ring, a substituted or unsubstituted 6-membered (hexagonal) ring, or a fused ring thereof,
X may be, e.g., N, NR^{b}, O, or S,
Z¹ to Z⁶ may each independently be, e.g., N, C, or CR^{c},
R^{b}, R^{c} and R² to R¹⁸ may each independently be, e.g., hydrogen, a hydroxy group, a halogen, a nitro group, a carboxyl group, a substituted or unsubstituted imine group, a substituted or unsubstituted C1 to C30 alkyl group, a substituted or unsubstituted C1 to C30 alkoxy group, a substituted or unsubstituted C6 to C30 aryl group, a substituted or unsubstituted C2 to C30 heteroaryl group, or a combination thereof, and
* is a linking point.

In an implementation, E may be a group of the following Group I-1.

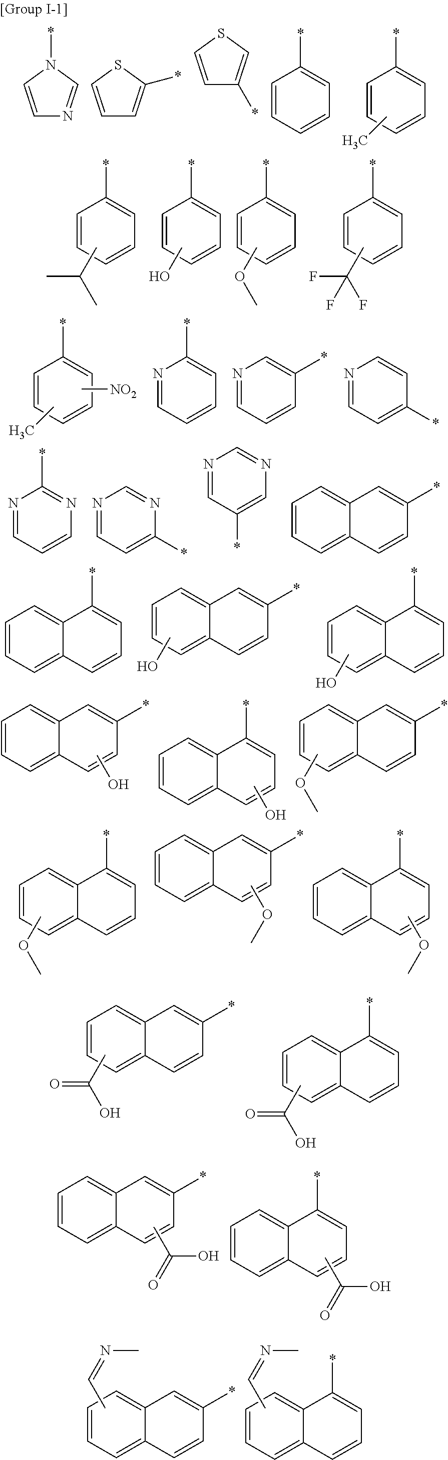

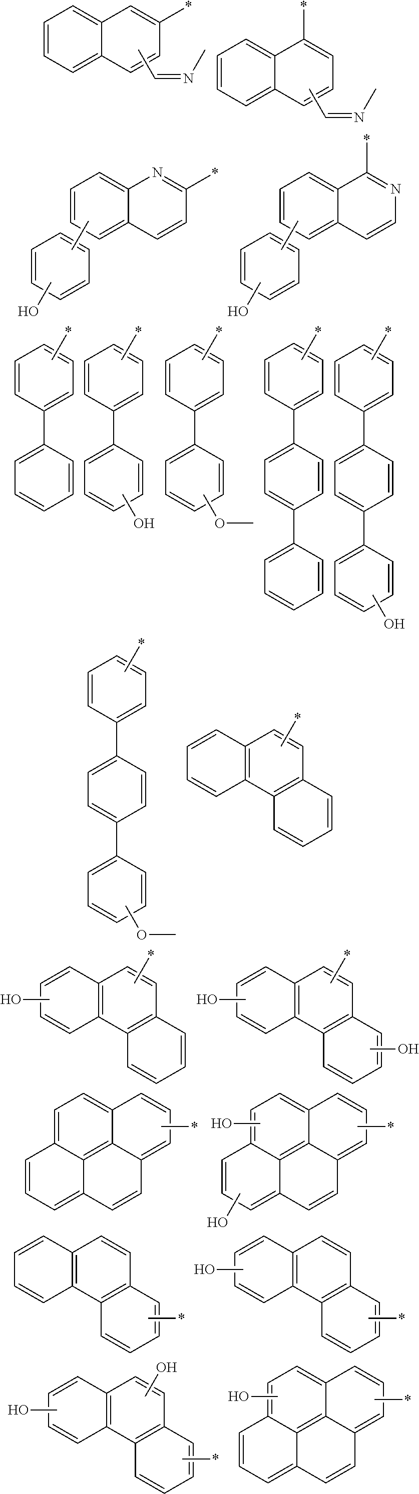

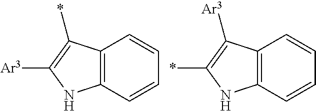

In Group I-1,
Ar³ may be, e. g., a C1 to C10 alkyl group or a C6 to C18 aryl group,
* is a linking point.

In an implementation, at least one of R¹ and E of Chemical Formula 1 and Chemical Formula 2 may be substituted with a hydroxy group (e.g., may be a substituted group in which a substituent thereof is a hydroxy group).

When a hydrophilic functional group such as hydroxy group is introduced, a cross-linking degree may be improved, and flatness may be further improved depending upon a type of the substrate.

In an implementation, E may be, e.g., a substituted or unsubstituted C6 to C30 non-fused aryl group, a substituted or unsubstituted naphthyl group, a substituted or unsubstituted quinolinyl group, or a substituted or unsubstituted indolyl group.

In an implementation, the substituted or unsubstituted C6 to C30 non-fused aryl group may be, e.g., a substituted or unsubstituted biphenyl group, a substituted or unsubstituted terphenyl group, a substituted or unsubstituted quaterphenyl group, or a substituted or unsubstituted pentaphenyl group.

In an implementation, the structural unit may be, e.g., a structural unit of the following Group II

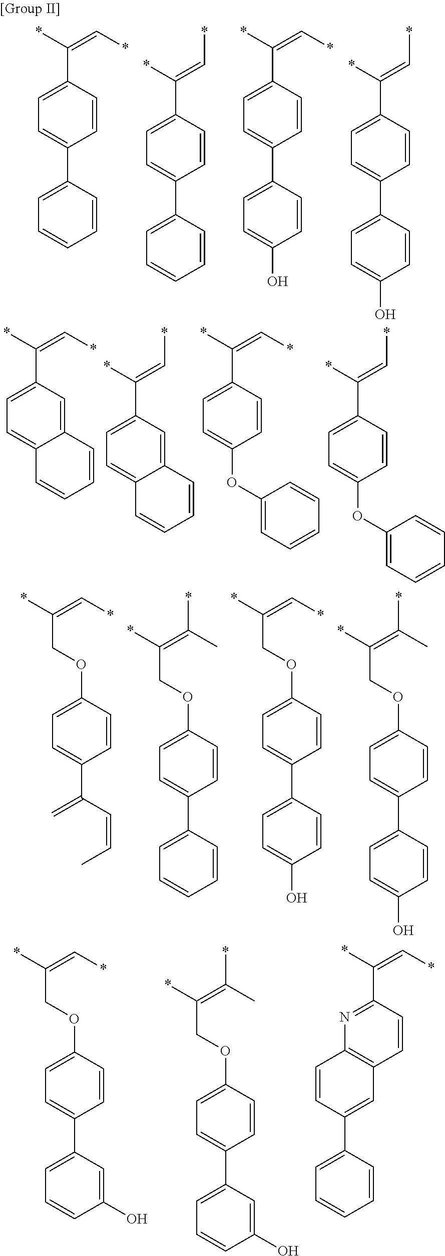

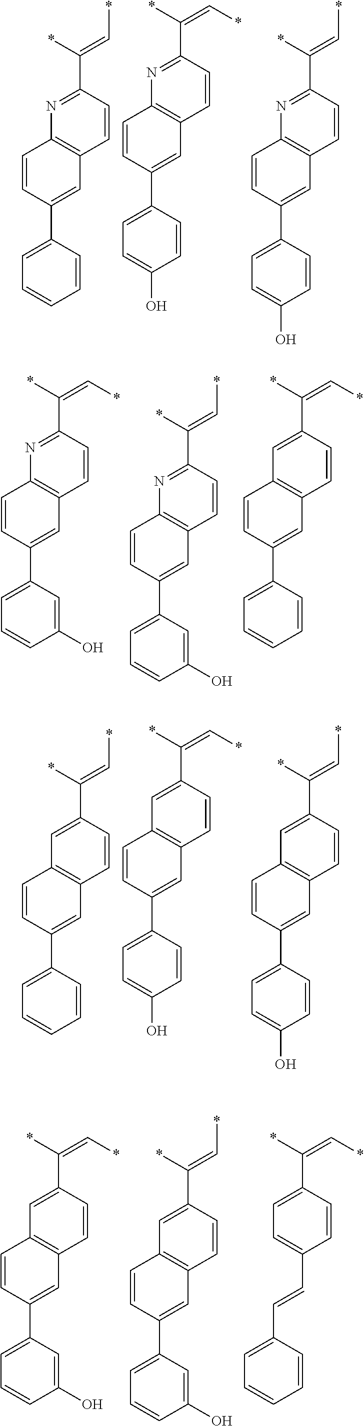

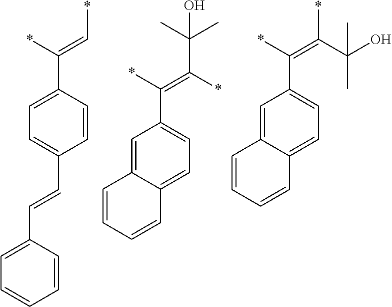

In Group II, * is a linking point.

In an implementation, when the polymer is applied to a process including UV exposure, an intermolecular cross-linking reaction may be induced by photocycloaddition mechanism between vinyl main chains.

For example, the polymer may show photosensitive characteristics without photosensitive additives, and may help control an etch resistance and a film thickness shrinkage by an exposure dose difference in each region of film using photosensitive characteristics, and also may provide a patterning function by itself even without a subsequent photolithography process.

In an implementation, the polymer may have a weight average molecular weight of, e.g., about 1,000 to about 200,000. When it has the weight average molecular weight within the ranges, it is possible to optimize carbon content and solubility for a solvent of an organic layer composition including the polymer (e.g., hardmask composition).

Another embodiment may provide an organic layer composition. The organic layer composition may include, e.g., the aforementioned polymer and a solvent.

The solvent may be a suitable solvent having sufficient dissolubility or dispersibility regarding the polymer and may include, e.g., propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, acetylacetone, ethyl 3-ethoxypropionate, 4-methoxybenzene, or tetrahydronaphthalene.

In an implementation, the polymer may be included in an amount of, e.g., about 0.1 wt % to about 50 wt %, about 0.5 wt % to about 40 wt %, about 1 wt % to about 30 wt %, or about 5 wt % to about 20 wt %, based on a total weight of the organic layer composition. When the polymer is included within the range, a thickness, surface roughness and planarization of the organic layer may be controlled.

In an implementation, the organic layer composition may further include, e.g., an additive of a surfactant, a cross-linking agent, a thermal acid generator, or a plasticizer.

The surfactant may include, e.g., a fluoroalkyl-based compound, an alkylbenzene sulfonate salt, an alkyl pyridinium salt, polyethylene glycol, or a quaternary ammonium salt.

The cross-linking agent may include, e.g., a melamine cross-linking agent, a substituted urea cross-linking agent, or a polymer cross-linking agent. In an implementation, it may be a cross-linking agent having at least two cross-linking forming substituents, e.g., a compound such as methoxymethylated glycoluril, butoxymethylated glycoluril, methoxymethylated melamine, butoxymethylated melamine, methoxymethylated benzoguanamine, butoxymethylated benzoguanamine, methoxymethylatedurea, butoxymethylatedurea, methoxymethylated thiourea, or butoxymethylated thiourea, or the like.

The cross-linking agent may be a cross-linking agent having high heat resistance. The cross-linking agent having high heat resistance may be a compound including a cross-linking substituent including an aromatic ring (e.g., a benzene ring, or a naphthalene ring) in the molecule.

The thermal acid generator may include, e.g., an acidic compound such as p-toluene sulfonic acid, trifluoromethane sulfonic acid, pyridinium p-toluene sulfonic acid, salicylic acid, sulfosalicylic acid, citric acid, benzoic acid, hydroxybenzoic acid, naphthalene carbonic acid, and the like or/and 2,4,4,6-tetrabromocyclohexadienone, benzointosylate, 2-nitrobenzyltosylate, other organosulfonic acid alkylester, or the like.

The additive may be included in an amount of, e.g., about 0.001 parts by weight to about 40 parts by weight, based on 100 parts by weight of the organic layer composition. Within the ranges, solubility may be improved while optical properties of the organic layer composition are not changed.

Another embodiment may provide an organic layer manufactured using the aforementioned organic layer composition. The organic layer may be, e.g., formed by coating the aforementioned organic layer composition on a substrate and heat-treating it for curing and may include, for example, a hardmask layer, a planarization layer, a sacrificial layer, a filler, and the like for an electronic device.

Hereinafter, a method of forming patterns using the aforementioned organic layer composition is described.

A method of forming patterns according to an embodiment may include, e.g., providing a material layer on a substrate, applying the organic layer composition including the polymer and the solvent on the material layer, heat-treating the organic layer composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed portion of the material layer.

The substrate may be, e.g., a silicon wafer, a glass substrate, or a polymer substrate.

The material layer may be a material to be finally patterned, e.g., a metal layer such as an aluminum layer and a copper layer, a semiconductor layer such as a silicon layer, or an insulation layer such as a silicon oxide layer and a silicon nitride layer. The material layer may be formed through a method, e.g., a chemical vapor deposition (CVD) process.

The organic layer composition may be the same as described above according to an embodiment, and may be applied by spin-on coating in a form of a solution. In an implementation, a thickness of the organic layer composition may be, e.g., about 50 Å to about 200,000 Å.

The heat-treating of the organic layer composition may be performed, e.g., at about 100° C. to about 700° C. for about 10 seconds to about 1 hour.

In an implementation, the method may further include forming a silicon-containing thin layer on the hardmask layer. The silicon-containing thin layer may be formed of a material, e.g., SiCN, SiOC, SiON, SiOCN, SiC, SiO, SiN, or the like.

In an implementation, the method may further include forming a bottom antireflective coating (BARC) on the upper surface of the silicon-containing thin layer or on the upper surface of the hardmask layer before forming the photoresist layer.

Exposure of the photoresist layer may be performed using, e.g. ArF, KrF, or EUV. After exposure, heat-treating may be performed at, e.g., about 100° C. to about 700° C.

The etching process of the exposed portion of the material layer may be performed through a dry etching process using an etching gas and the etching gas may include, e.g., CHF₃, CF₄, Cl₂, BCl₃, and a mixed gas thereof.

The etched material layer may be formed in a plurality of patterns, and the plurality of patterns may include, e.g., a metal pattern, a semiconductor pattern, an insulation pattern, or the like. For example, the patterns may include diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### SYNTHESIS EXAMPLES

### Synthesis Example 1

After mounting a distillation device on a flask, 5 g of 4-ethynylbiphenyl and 1 g of azobisisobutyronitrile (hereinafter, AIBN) were added thereto, followed by an addition of 18 g of dichlorobenzene, and dissolved by stirring. The reaction proceeded for 24 hours by heating the same at 100° C. and then cooled down to 20° C. 10 g of tetrahydrofuran was added into the reaction solution to dilute the solution, and the diluted solution was dropped into 1 L of n-hexane/isopropyl alcohol mixed solution (7/3) to precipitate a compound. The precipitated compound was filtered and washed with n-hexane and vacuum-dried to provide a polymer including a structural unit represented by Chemical Formula 1a.

A weight average molecular weight (Mw) of the polymer measured by a gel permeation chromatography (GPC) was 1,500.

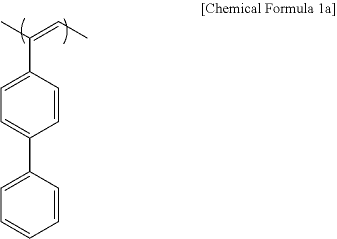

### Synthesis Example 2

A polymer including a structural unit represented by Chemical Formula 1b was prepared in accordance with the same procedure as in Synthesis Example 1, except that 5.5 g of 4-ethynyl-[1,1′-biphenyl]-4-ol was used instead of 5 g of 4-ethynylbiphenyl in Synthesis Example 1.

A weight average molecular weight measured using a gel permeation chromatography (GPC) was 2,000.

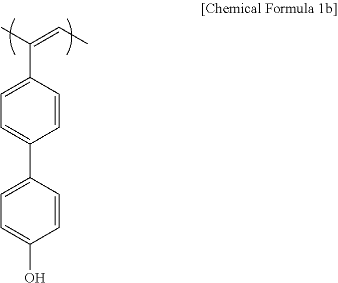

### Synthesis Example 3

A polymer including a structural unit represented by Chemical Formula 1c was prepared in accordance with the same procedure as in Synthesis Example 1, except that 4.3 g of 2-ethynyl-naphthalene was used instead of 5 g of 4-ethynylbiphenyl in Synthesis Example 1.

A weight average molecular weight of the polymer measured using a gel permeation chromatography was 1,300.

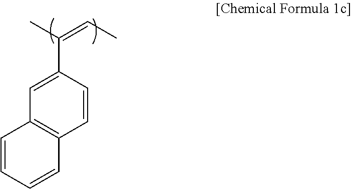

### Synthesis Example 4

A polymer including a structural unit represented by Chemical Formula 1d was prepared in accordance with the same procedure as in Synthesis Example 1, except that 5.5 g of 1-ethynyl-4-phenoxybenzene was used instead of 5 g of 4-ethynylbiphenyl in Synthesis Example 1.

A weight average molecular weight of the polymer measured using a gel permeation chromatography was 1,500.

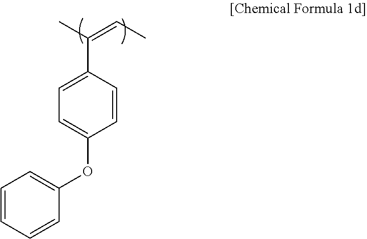

### Synthesis Example 5

A polymer including a structural unit represented by Chemical Formula 1e was prepared in accordance with the same procedure as in Synthesis Example 1, except that 6.3 g of 4′-(2-propyn-1-yloxy)[1,1′-biphenyl]-4-ol was used instead of 5 g of 4-ethynylbiphenyl in Synthesis Example 1.

A weight average molecular weight of the polymer measured using a gel permeation chromatography was 1,500.

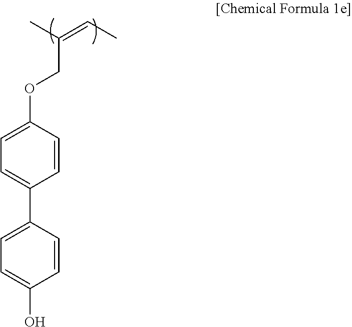

### Synthesis Example 6

A polymer including a structural unit represented by Chemical Formula 1f was prepared in accordance with the same procedure as in Synthesis Example 1, except that 6.9 g of 3-(2-ethynyl-6-quinolinyl)-phenol was used instead of 5 g of 4-ethynylbiphenyl in Synthesis Example 1.

A weight average molecular weight of the polymer measured using a gel permeation chromatography was 1,500.

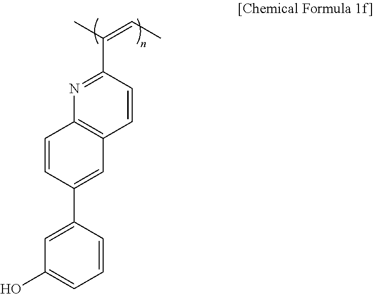

### Synthesis Example 7

A polymer including a structural unit represented by Chemical Formula 1g was prepared in accordance with the same procedure as in Synthesis Example 1, except that 5.7 g of 1-ethynyl-4-(2-phenylethenyl)benzene was used instead of 5 g of 4-ethynylbiphenyl in Synthesis Example 1.

A weight average molecular weight of the polymer measured using a gel permeation chromatography was 1,500.

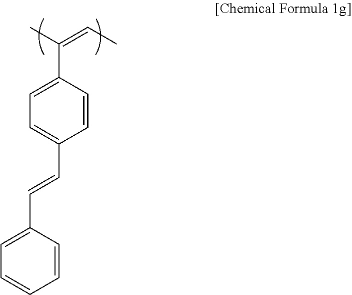

### Synthesis Example 8

After mounting a distillation device on a flask filled with nitrogen gas, 5 g of 2-methyl-4-(naphthalen-2-yl)but-3-yn-2-ol (manufactured by Rieke Metals NCS Brand) and 0.5 g of WCl₆ were added thereto and then added with 18 g of dichlorobenzene and dissolved by stirring the same. The reaction proceeded for 6 hours by heating the same at 40° C. and then cooled down to 20° C. 10 g of tetrahydrofuran was added into the reaction solution to dilute the solution, and the diluted solution added to 2 L of methanol to precipitate a compound. The precipitated compound was filtered and washed with n-hexane and vacuum-dried to provide a polymer including a structural unit represented by Chemical Formula 1h. A weight average molecular weight of the polymer measured using a gel permeation chromatography was 3,000.

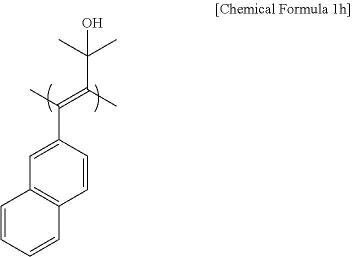

### Comparative Synthesis Example 1

A polymer including a structural unit represented by Chemical Formula Y1 was prepared in accordance with the same procedure as in Synthesis Example 1, except that 5.5 g of hydroxystyrene was used instead of 5 g of 4-ethynylbiphenyl in Synthesis Example 1.

A weight average molecular weight measured using a gel permeation chromatography was 3,800.

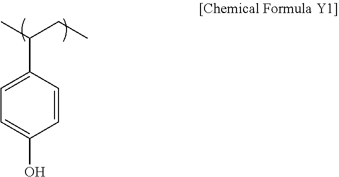

### Comparative Synthesis Example 2

A polymer including a structural unit represented by Chemical Formula Y2 was prepared in accordance with the same procedure as in Comparative Synthesis Example 1, except that 7 g of 4-vinylbiphenyl was used instead of 5.5 g of hydroxystyrene in Comparative Synthesis Example 1.

A weight average molecular weight of the polymer measured using a gel permeation chromatography was 4,500.

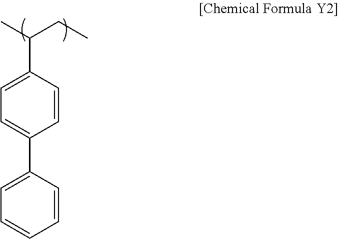

### Forming Organic Layer

### Example 1 to 8, Comparative Example 1 and 2

1 g of each of the polymers obtained from Synthesis Examples 1 to 8 and Comparative Synthesis Examples 1 and 2 was weighted and dissolved in 10 g of propylene glycol monomethyl ether acetate (PGMEA) and stirred for 24 hours and then filtered with a 0.1 m filter to provide a hardmask composition. The composition was coated on a silicon wafer according to a spin-coating method and heated at 350° C. for 2 minutes under an air atmosphere to provide a thin film.

### Evaluation

### Evaluation 1: Etch Resistance

The thicknesses of the organic layers according to Examples 1 to 8, Comparative Examples 1 and 2 were measured. Subsequently, the organic layers were dry-etched using CFₓ/Ar/O₂ mixed gas for 50 seconds and then the thicknesses of the organic layers were measured again.

The thicknesses of the organic layers before and after the dry etching and their etching times were used to calculate a bulk etch rate (BER) according to Calculation Equation 1 and grades according to references of Table 2 are shown in Table 1.

Etch rate (Å/s)=(Initial organic layer thickness−organic layer thickness after etching)/etching time [Calculation Equation 1]

TABLE 1

| | CFₓ/Ar/O₂ |
|---|---|
| | etch rate (Å/s) |
| Example 1 | B |
| Example 2 | B |
| Example 3 | A |
| Example 4 | B |
| Example 5 | B |
| Example 6 | A |
| Example 7 | A |
| Example 8 | A |
| Comparative Example 1 | C |
| Comparative Example 2 | C |

TABLE 2

| | Evaluation reference |
|---|---|
| Grade | of etch resistance |
| A | etch rate < 25 Å/s |
| B | 25 Å/s ≤ etch rate ≤ 30 Å/s |
| C | etch rate > 30 Å/s |

Referring to Tables 1 and 2, it may be seen that the thin films obtained from the hardmask compositions according to Examples 1 to 8 exhibited improved bulk etch characteristics and sufficient etch resistance for the etching gas, compared with the thin films obtained from the hardmask compositions according to Comparative Examples 1 and 2.

By way of summation and review, according to small-sizing the pattern to be formed, there may be issues providing a fine pattern having an excellent profile by using some lithographic techniques. Accordingly, an organic layer, called a hardmask layer, may be formed between the material layer and the photoresist layer to provide a fine pattern.

The hardmask layer may play a role of an intermediate layer for transferring the fine pattern of photoresist to the material layer through the selective etching process. Accordingly, the hardmask layer may have characteristics such as heat resistance and etch resistance to be tolerated during the multiple etching processes.

One or more embodiments may provide a polymer that may be effectively applicable to a hardmask layer.

When the polymer according to an embodiment is used as an organic layer material, an organic layer having improved etch resistance may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of forming patterns, the method comprising:
providing a material layer on a substrate,
applying a hardmask composition on the material layer,
heat-treating the hardmask composition to form a hardmask layer,
forming a photoresist layer on the hardmask layer,
exposing and developing the photoresist layer to form a photoresist pattern,
selectively removing the hardmask layer using the photoresist pattern to expose a portion of the material layer, and
etching an exposed portion of the material layer,
wherein:
the hardmask composition includes:
a solvent, and
a polymer including a structural unit represented by one of Chemical Formula 1c, Chemical Formula 1f, Chemical Formula 1g, and Chemical Formula 1h:

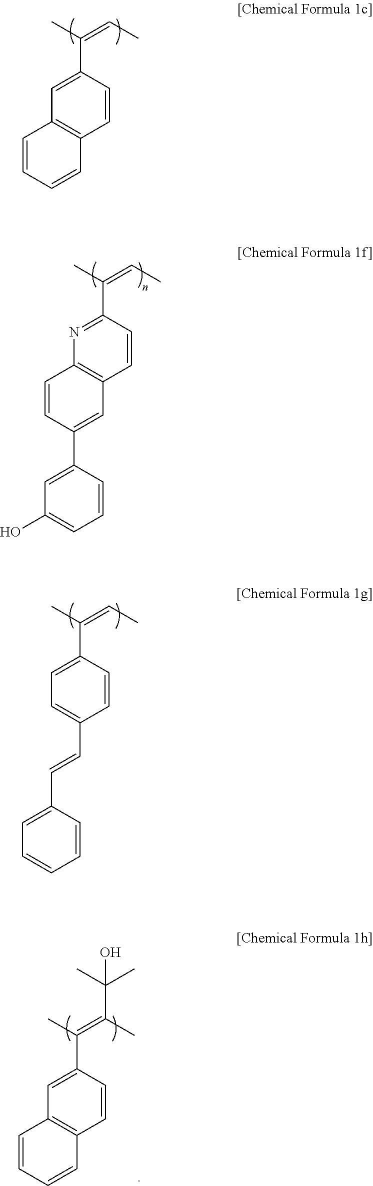

2. The method as claimed in claim 1, wherein the polymer has a weight average molecular weight of about 1,000 to about 200,000.

3. The method as claimed in claim 1, wherein the substrate is a silicon wafer, a glass substrate, or a polymer substrate.

4. The method as claimed in claim 1, wherein the material layer is a metal layer, a semiconductor layer, or an insulation layer.

5. The method as claimed in claim 1, wherein applying a hardmask composition on the material layer includes spin-on coating.

6. The method as claimed in claim 12, wherein a thickness of the hardmask composition is about 50 Å to about 200,000 Å.

7. The method as claimed in claim 1, wherein heat-treating the hardmask composition is performed at about 100° C. to about 700° C. for about 10 seconds to about 1 hour.

8. The method as claimed in claim 1, further comprising forming a silicon-containing thin layer on the hardmask layer.

9. The method as claimed in claim 8, wherein the silicon-containing thin layer includes SiCN, SiOC, SiON, SiOCN, SiC, SiO, or SiN.

10. The method as claimed in claim 8, further comprising forming a bottom antireflective coating on an upper surface of the silicon-containing thin layer or on an upper surface of the hardmask layer, prior to forming the photoresist layer.

11. The method as claimed in claim 1, wherein exposing the photoresist layer is performed using ArF, KrF, or EUV.

12. The method as claimed in claim 1, further comprising heat-treating the photoresist layer after exposing the photoresist layer, the heat-treating being performed at about 100° C. to about 700° C.

13. The method as claimed in claim 1, wherein etching the exposed portion of the material layer includes performing a dry etching process using an etching gas that includes CHF₃, CF₄, Cl₂, BCl₃, or a mixed gas thereof.
